(19) United States
(12) Patent Application Publication
(10) Pub. No.: US 2026/0182418 A1
(43) Pub. Date: Jun. 25, 2026

(54) POWER MODULE

(71) Applicant: SHINKO ELECTRIC INDUSTRIES CO., LTD., Nagano (JP)

(72) Inventor: Jumpei TOKUTAKE, Nagano (JP)

(21) Appl. No.: 19/425,033

(22) Filed: Dec. 18, 2025

(30) Foreign Application Priority Data
Dec. 24, 2024 (JP) 2024-227388

(51) Int. Cl. H10W 70/65; H10W 70/00; H10W 74/10; H10W 90/00; H10W 90/10

(52) U.S. Cl. CPC H10W 70/65; H10W 70/099; H10W 74/114; H10W 90/10; H10W 90/734

(57) ABSTRACT

A power module includes a first semiconductor device having first and second electrodes at opposite surfaces, a second semiconductor device having third and fourth electrodes at opposite surfaces, an insulating base having the first and second semiconductor devices on opposite surfaces, a first conductive member penetrating the insulating base and coupled to the first electrode, a second conductive member coupled to the second electrode, a third conductive member coupled to the second conductive member, a fourth conductive member penetrating the insulating base and coupled to the third electrode, a fifth conductive member coupled to the fourth electrode, a sixth conductive member coupled to the fifth conductive member, and an encapsulation member encapsulating the first and second semiconductor devices. The first and sixth conductive members are coupled, the third and fourth conductive members overlap in a plan view, and the third and fourth conductive members extend outside the encapsulation member.

### CROSS-REFERENCE TO RELATED APPLICATIONS

This application is based upon and claims priority to Japanese Patent Application No. 2024-227388, filed on Dec. 24, 2024, the entire contents of which are incorporated herein by reference.

### FIELD

Certain aspects of the embodiments discussed herein are related to power modules and methods for manufacturing power modules.

### BACKGROUND

A proposed power module has a semiconductor device adhered to one surface of an insulating base material, and a conductive layer provided on the other surface of the insulating base and connected to an electrode of the semiconductor device.

Related art include Japanese Laid-Open Patent Publication No. 2020-057771 and Japanese Laid-Open Patent Publication No. 2020-167233, for example.

In recent years, there are increasing demands for further reducing an inductance of the power module.

### SUMMARY

Accordingly, it is an object in one aspect of the embodiments of the present disclosure to provide a power module and a method for manufacturing the power module, capable of reducing the inductance of the power module.

According to one aspect of the embodiments of the present disclosure, a power module includes a first semiconductor device having a first surface and a second surface opposite to the first surface, a first electrode provided at the first surface, and a second electrode provided at the second surface; a second semiconductor device having a third surface and a fourth surface opposite to the third surface, a third electrode provided at the third surface, and a fourth electrode provided at the fourth surface; an insulating base material having a fifth surface to which the first semiconductor device and the second semiconductor device are adhered and a sixth surface opposite to the fifth surface; a first conductive member penetrating the insulating base material, electrically connected to the first electrode, and formed on the sixth surface; a second conductive member electrically connected to the second electrode; a third conductive member adhered to the fifth surface and electrically connected to the second conductive member; a fourth conductive member penetrating the insulating base material, electrically connected to the third electrode, and formed on the sixth surface; a fifth conductive member electrically connected to the fourth electrode; a sixth conductive member adhered to the fifth surface and electrically connected to the fifth conductive member; and an encapsulation member configured to encapsulate the first semiconductor device and the second semiconductor device, wherein the first conductive member and the sixth conductive member are electrically connected, the third conductive member and the fourth conductive member overlap each other in a plan view, and the third conductive member and the fourth conductive member extend to an outside of the encapsulation member.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a top view illustrating a power module according to a first embodiment;

FIG. 2 is a bottom view illustrating the power module according to the first embodiment;

FIG. 3 is a first top view illustrating a part of the power module according to the first embodiment;

FIG. 4 is a second top view illustrating a part of the power module according to the first embodiment;

FIG. 5A and FIG. 5B are cross sectional views schematically illustrating the power module according to the first embodiment;

FIG. 6 is a circuit diagram illustrating the power module according to the first embodiment;

FIG. 7A and FIG. 7B are first cross sectional views schematically illustrating a method for manufacturing the power module according to the first embodiment;

FIG. 8A and FIG. 8B are second cross sectional views schematically illustrating the method for manufacturing the power module according to the first embodiment;

FIG. 9A and FIG. 9B are third cross sectional views schematically illustrating the method for manufacturing the power module according to the first embodiment;

FIG. 10A and FIG. 10B are fourth cross sectional views schematically illustrating the method for manufacturing the power module according to the first embodiment;

FIG. 11A and FIG. 11B are fifth cross sectional views schematically illustrating the method for manufacturing the power module according to the first embodiment;

FIG. 12A and FIG. 12B are sixth cross sectional views schematically illustrating the method for manufacturing the power module according to the first embodiment;

FIG. 13A and FIG. 13B are seventh cross sectional views schematically illustrating the method for manufacturing the power module according to the first embodiment;

FIG. 14 is a top view illustrating a lead frame;

FIG. 15A and FIG. 15B are cross sectional views schematically illustrating a power module according to a reference example; and

FIG. 16A and FIG. 16B are cross sectional views schematically illustrating a power module according to a second embodiment.

### DESCRIPTION OF EMBODIMENTS

Hereinafter, embodiments of the present disclosure will be described in detail with reference to the accompanying drawings. In the present specification and the drawings, constituent elements or components having substantially the same functional configuration are designated by the same reference numerals, and a redundant description thereof may be omitted. In addition, in the present disclosure, an X-axis (X1-X2 direction), a Y-axis (Y1-Y2 direction), and a Z-axis (Z1-Z2 direction) denote mutually orthogonal directions. A plane including the X-axis and the Y-axis is referred to as an XY-plane, a plane including the Y-axis and the Z-axis is referred to as a YZ-plane, and a plane including the Z-axis and the X-axis is referred to as a ZX-plane. For the sake of convenience, the Z1-Z2 direction is defined as a vertical direction, the Z1-side is defined as an upper side, and the Z2-side is defined as a lower side. In addition, a plan view of an object refers to a view of the object viewed from the Z1-side in a direction perpendicular to the XY-plane, and a planar shape of the object refers to a shape of the object in the plan view viewed from the Z1-side. However, a power module may be used in an upside-down state or may be disposed at an arbitrary angle in use.

### First Embodiment

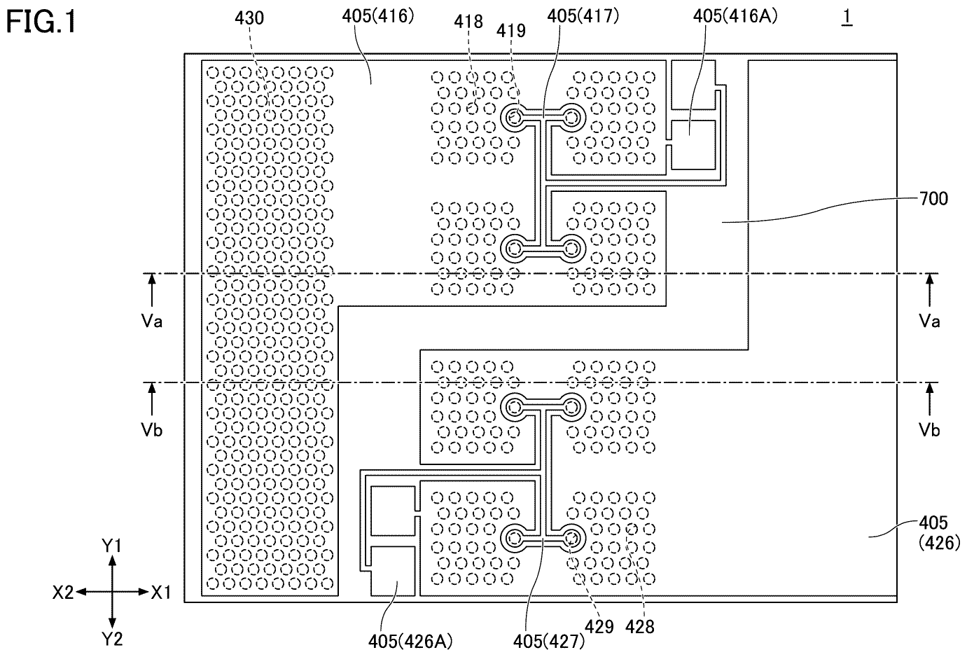

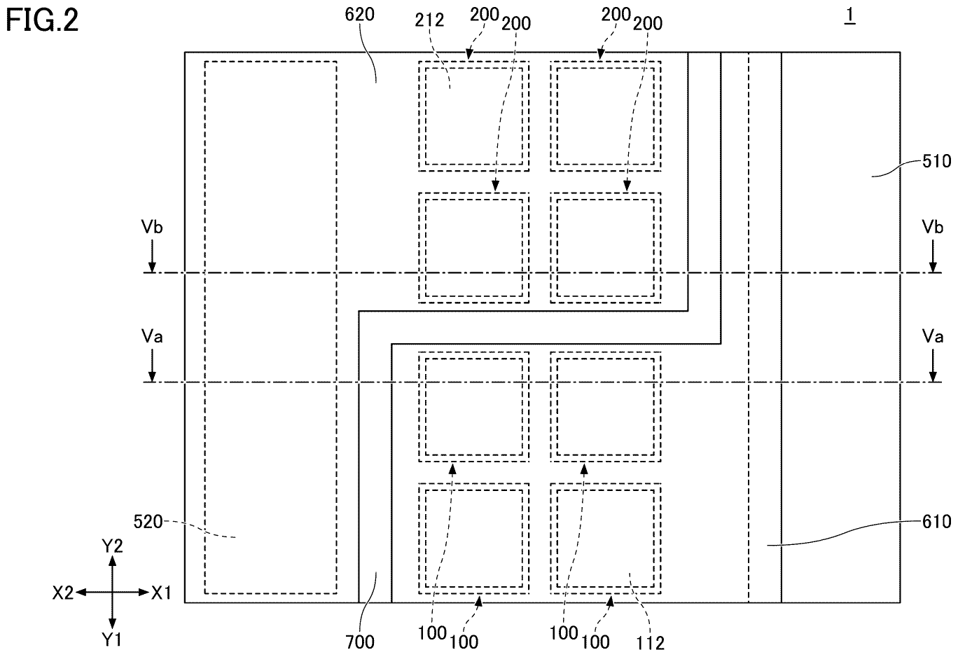

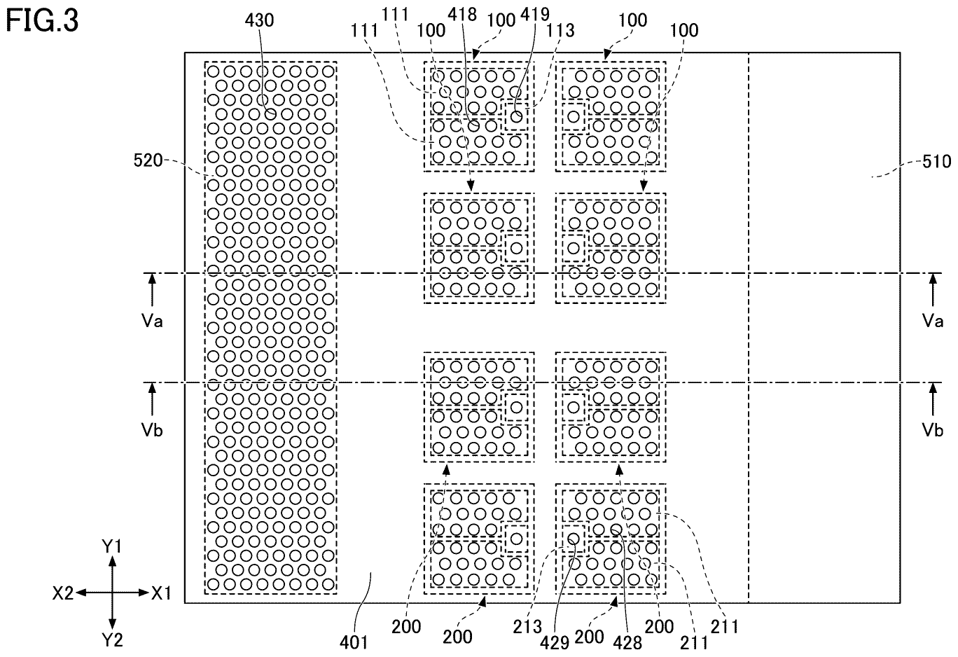

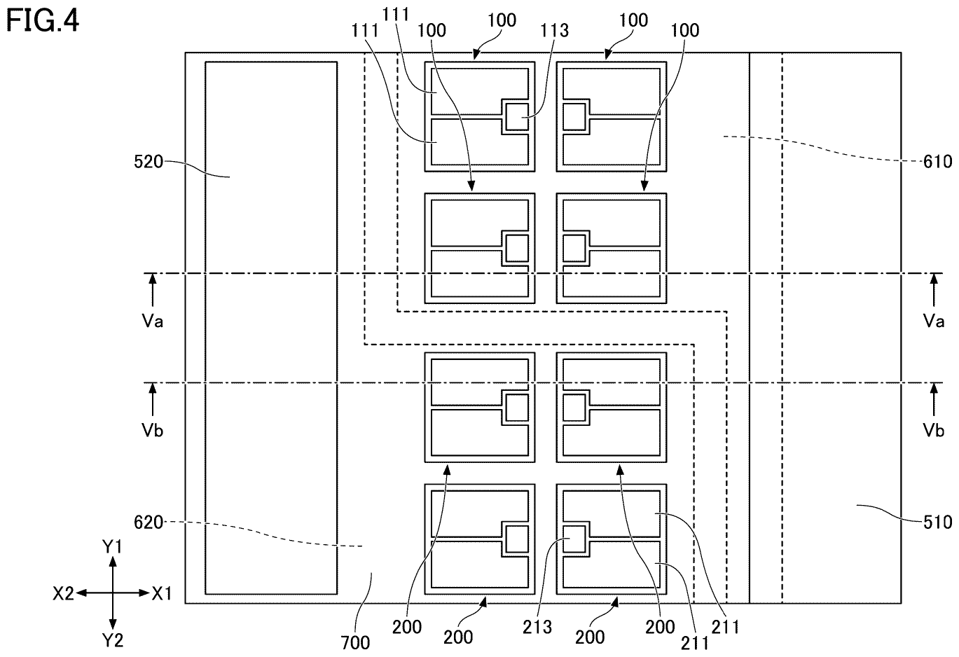

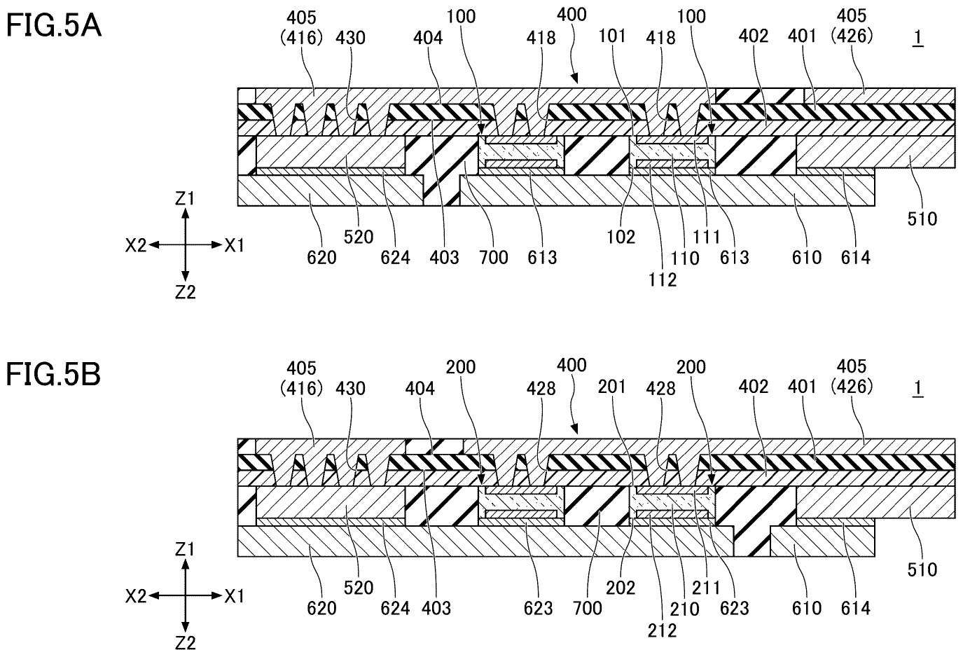

A first embodiment will be described. A first embodiment relates to a power module. FIG. 1 is a top view illustrating the power module according to a first embodiment. FIG. 2 is a bottom view illustrating the power module according to the first embodiment. FIG. 3 and FIG. 4 are top views illustrating a part of the power module according to the first embodiment. FIG. 5A and FIG. 5B are cross sectional views schematically illustrating the power module according to the first embodiment. FIG. 5A is a cross sectional view taken along a line Va-Va in FIG. 1 through FIG. 4. FIG. 5B is a cross sectional view taken along a line Vb-Vb in FIG. 1 through FIG. 4.

As illustrated in FIG. 1 through FIG. 4, FIG. 5A and FIG. 5B, a power module 1 according to the first embodiment includes four semiconductor devices 100, four semiconductor devices 200, a flexible wiring board 400, a shim 510, a shim 520, a lead terminal 610, a lead terminal 620, and a mold 700.

The semiconductor devices 100 and 200 are formed using silicon (Si) or silicon carbide (SiC), for example. The semiconductor devices 100 and 200 may be formed using gallium nitride (GaN) or gallium arsenide (GaAs). For example, the semiconductor devices 100 and 200 may be insulated gate bipolar transistors (IGBTs) or metal-oxide-semiconductor field-effect transistors (MOSFETs). The planar shape of the semiconductor devices 100 and 200 is a rectangular shape, for example. A thickness of the semiconductor devices 100 and 200 is 50 μm or greater and 500 μm or less, for example.

As illustrated in FIG. 4 and FIG. 5A, the semiconductor device 100 has a first surface 101, and a second surface 102 opposite to the first surface 101. The semiconductor device 100 includes a main body 110, an electrode 111, an electrode 112, and an electrode 113. The electrode 111 and the electrode 113 are provided at the first surface 101, and the electrode 112 is provided at the second surface 102. For example, the electrode 111, the electrode 112, and the electrode 113 are a source electrode, a drain electrode, and a gate electrode, respectively. The semiconductor device 100 is an example of a first semiconductor device, the first surface 101 is an example of a first surface, and the second surface 102 is an example of a second surface. The electrode 111 is an example of a first electrode, and the electrode 112 is an example of a second electrode.

As illustrated in FIG. 4 and FIG. 5B, the semiconductor device 200 has a first surface 201, and a second surface 202 opposite to the first surface 201. The semiconductor device 200 includes a main body 210, an electrode 211, an electrode 212, and an electrode 213. The electrode 211 and the electrode 213 are provided at the first surface 201, and the electrode 212 is provided at the second surface 202. For example, the electrode 211, the electrode 212, and the electrode 213 are a source electrode, a drain electrode, and a gate electrode, respectively. The semiconductor device 200 is an example of a second semiconductor device, the first surface 201 is an example of a third surface, and the second surface 202 is an example of a fourth surface. The electrode 211 is an example of a third electrode, and the electrode 212 is an example of a fourth electrode.

A material used for the electrode 111, the electrode 112, the electrode 113, the electrode 211, the electrode 212, and the electrode 213 (these electrodes may hereinafter be collectively referred to as “electrodes”) may be selected from metals, such as aluminum (Al), copper (Cu) or the like, or selected from alloys including at least one metal selected from these metals, for example. A surface treatment layer may be formed on a surface of the electrode, as necessary. Examples of the surface treatment layer include a gold (Au) layer, a nickel (Ni) layer/Au layer (a metal layer in which a Ni layer and an Au layer are stacked in this order), a Ni layer/palladium (Pd) layer/Au layer (a metal layer in which a Ni layer, a Pd layer, and an Au layer are stacked in this order), or the like. The Au layer, the Ni layer, and the Pd layer may be metal layers (electroless plating metal layers) formed by an electroless plating, for example. Further, the Au layer may be a metal layer made of Au or an Au alloy, the Ni layer may be a metal layer made of Ni or an Ni alloy, and the Pd layer may be a metal layer made of Pd or a Pd alloy.

The shims 510 and 520 are metal plates, such as Cu plates or the like. A thickness of the shims 510 and 520 is approximately the same as the thickness of the semiconductor devices 100 and 200. That is, the thickness of the shims 510 and 520 is 50 μm or greater and 500 μm or less, for example. The shim 510 is an example of a third conductive member and a first conductive shim, and the shim 520 is an example of a sixth conductive member and a second conductive shim.

As illustrated in FIG. 5A and FIG. 5B, the flexible wiring board 400 includes an insulating base material 401, an insulating adhesive layer 402, and an interconnect layer 405. The insulating base material 401 has a first surface 403, and a second surface 404 opposite to the first surface 403. The adhesive layer 402 is provided on the first surface 403, and the interconnect layer 405 is provided on the second surface 404. The adhesive layer 402 may be provided on the entire first surface 403. The first surface 403 is an example of a fifth surface, and the second surface 404 is an example of a sixth surface.

The insulating base material 401 is a resin film, for example. Examples of a material used for the resin film include insulating resins, such as a polyimide resin, a polyethylene resin, an epoxy resin, or the like. The insulating base material 401 has flexibility, for example. Here, the flexibility refers to a property that enables bending or flexing. The planar shape of the insulating base material 401 is a rectangular shape, for example. A thickness of the insulating base material 401 is 50 μm or greater and 100 μm or less, for example.

The semiconductor devices 100, the semiconductor devices 200, the shim 510, and the shim 520 are adhered to the first surface 403 of the insulating base material 401 by the adhesive layer 402. The first surfaces 101 of the semiconductor devices 100 and the first surfaces 201 of the semiconductor devices 200 face the first surface 403 of the insulating base material 401. The four semiconductor devices 100 are arranged in a matrix of two rows and two columns in the plan view, and the four semiconductor devices 200 are arranged in a matrix of two rows and two columns in the plan view. The four semiconductor devices 100 are located on the Y1-side of the four semiconductor devices 200. The shim 510 is located on the X1-side of the four semiconductor devices 100 and the four semiconductor devices 200, and the shim 520 is located on the X2-side of the four semiconductor devices 100 and the four semiconductor devices 200.

As illustrated in FIG. 3, FIG. 5A, and FIG. 5B, a through hole 418 reaching the electrode 111, a through hole 419 reaching the electrode 113, a through hole 428 reaching the electrode 211, a through hole 429 reaching the electrode 213, and a through hole 430 reaching the shim 520 are formed in the insulating base material 401 and the adhesive layer 402. A plurality of through holes 418, 428, and 430 may be formed, respectively.

Examples of a material used for the adhesive layer 402 include an epoxy-based adhesive, a polyimide-based adhesive, silicone-based adhesive, or the like, for example. A thickness of the adhesive layer 402 is 20 μm or greater and 40 μm or less, for example.

As illustrated in FIG. 1, FIG. 5A, and FIG. 5B, the interconnect layer 405 includes an interconnect 416, an interconnect 417, an interconnect 416A, an interconnect 426, an interconnect 427, and an interconnect 426A. The interconnect 416 is connected to the electrode 111 through the through hole 418, and is connected to the shim 520 through the through hole 430. The interconnect 416 is in contact with the electrode 111 and the shim 520. The interconnect 417 is connected to the electrode 113 through the through hole 419. The interconnect 417 is in contact with the electrode 113. The interconnect 416A is connected to the interconnect 416. The interconnect 426 is connected to the electrode 211 through the through hole 428. The interconnect 426 is in contact with the electrode 211. The interconnect 427 is connected to the electrode 213 through the through hole 429. The interconnect 427 is in contact with the electrode 213. The interconnect 426A is connected to the interconnect 426. The interconnect 416 is an example of a first conductive member, and the interconnect 426 is an example of a fourth conductive member.

The interconnect 416 includes a via interconnect filling the through hole 418, a via interconnect filled in the through hole 430, and an interconnect pattern formed on the second surface 404 of the insulating base material 401. The interconnect 417 includes a via interconnect filled in the through hole 419, and an interconnect pattern formed on the second surface 404 of the insulating base material 401. The interconnect 416A includes an interconnect pattern formed on the second surface 404 of the insulating base material 401.

The interconnect 426 includes a via interconnect filled in the through hole 428, and an interconnect pattern formed on the second surface 404 of the insulating base material 401. The interconnect 427 includes a via interconnect filled in the through hole 429, and an interconnect pattern formed on the second surface 404 of the insulating base material 401. The interconnect 426A includes an interconnect pattern formed on the second surface 404 of the insulating base material 401.

As illustrated in FIG. 5A and FIG. 5B, the lead terminal 610 is bonded to the electrode 112 of the semiconductor device 100 by a conductive bonding material 613, and is bonded to the shim 510 by a conductive bonding material 614. The lead terminal 620 is bonded to the electrode 212 of the semiconductor device 200 by a conductive bonding material 623, and is bonded to the shim 520 by a conductive bonding material 624. The lead terminals 610 and 620 are formed of a lead frame made of Cu, for example. The conductive bonding materials 613, 614, 623, and 624 are solder layers or sintered metal layers, for example. The conductive bonding materials 613, 614, 623, and 624 may be made of a conductive paste. The lead terminal 610 is an example of a second conductive member, and the lead terminal 620 is an example of a fifth conductive member. The conductive bonding material 613 is an example of a first conductive bonding material, and the conductive bonding material 614 is an example of a second conductive bonding material. The conductive bonding material 623 is an example of a third conductive bonding material, and the conductive bonding material 624 is an example of a fourth conductive bonding material.

As illustrated in FIG. 1, FIG. 2, FIG. 5A, and FIG. 5B, the mold 700 encapsulates the semiconductor devices 100 and the semiconductor devices 200. A part of a surface of the shim 510 on the Z2-side, a surface of the interconnect layer 405 on the Z1-side, a surface of the lead terminal 610 on the Z2-side, and a surface of the lead terminal 620 on the Z2-side are exposed from the mold 700. The interconnect 426 and the shim 510 extend from the mold 700 toward the X1-side. That is, the interconnect 426 and the shim 510 extend to the outside of the mold 700. The mold 700 is an example of an encapsulation member.

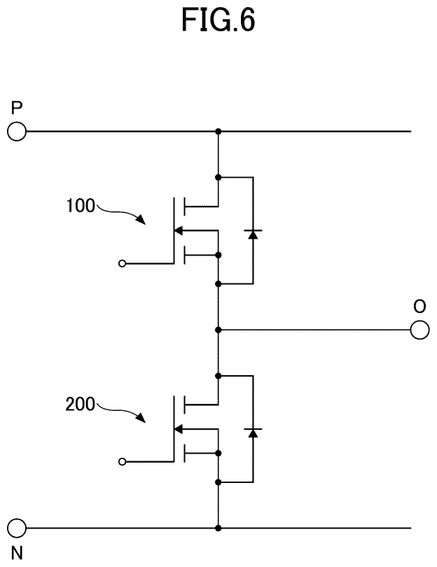

Next, a circuit configuration of the power module 1 according to the first embodiment will be described. FIG. 6 is a circuit diagram illustrating the power module according to the first embodiment. Although one semiconductor device 100 of the four semiconductor devices 100 and one semiconductor device 200 of the four semiconductor devices 200 are illustrated in FIG. 6 for the sake of convenience, the four semiconductor devices 100 are connected in parallel to one another and the four semiconductor devices 200 are connected in parallel to one another. The power module 1 has a half-bridge circuit illustrated in FIG. 6.

As illustrated in FIG. 6, the electrode 112 of the semiconductor device 100 is electrically connected to the shim 510 serving as a P terminal, via the lead terminal 610, and the electrode 211 of the semiconductor device 200 is electrically connected to the interconnect 426 serving as an N terminal. In addition, the electrode 111 of the semiconductor device 100 is electrically connected to the interconnect 416 serving as an O terminal, and the electrode 212 of the semiconductor device 200 is electrically connected to the interconnect 416 serving as an O terminal via the lead terminal 620 and the shim 520. The P terminal is an input terminal on the positive electrode side, the N terminal is an input terminal on the negative electrode side, and the O terminal is an output terminal. Accordingly, currents flow through the shim 510 and the interconnect 426 in opposite directions.

Moreover, the electrode 113 of the semiconductor device 100 is electrically connected to the interconnect 417 serving as a control terminal, and the electrode 213 of the semiconductor device 200 is electrically connected to the interconnect 427 serving as a control terminal. Hence, a control signal is input to the electrode 113 of the semiconductor device 100 from the interconnect 417, and a control signal is input to the electrode 213 of the semiconductor device 200 from the interconnect 427. Further, the interconnect 416 is electrically connected to interconnect 416A serving as a sense source terminal, and the interconnect 426 is electrically connected to interconnect 426A serving as a sense source terminal.

As described above, in the power module 1, the semiconductor device 100 is adhered to the first surface 403 of the insulating base material 401, the interconnect 416 is formed on the second surface 404 of the insulating base material 401, the electrode 111 of the semiconductor device 100 is electrically connected to the interconnect 416, and the electrode 112 of the semiconductor device 100 is electrically connected to the shim 510 via the lead terminal 610. In addition, the semiconductor device 200 is adhered to the first surface 403 of the insulating base material 401, the interconnect 426 is formed on the second surface 404 of the insulating base material 401, the electrode 211 of the semiconductor device 200 is electrically connected to the interconnect 426, and the electrode 212 of the semiconductor device 200 is electrically connected to the shim 520 via the lead terminal 620. The interconnect 416 and the shim 520 are electrically connected to each other. The half-bridge circuit is configured in the manner described above. The shim 510 and the interconnect 426 overlap each other in the plan view. Accordingly, it is possible to reduce a distance between the shim 510 and the interconnect 426 through which the currents flow in opposite directions, and an inductance of the power module 1 can be significantly reduced.

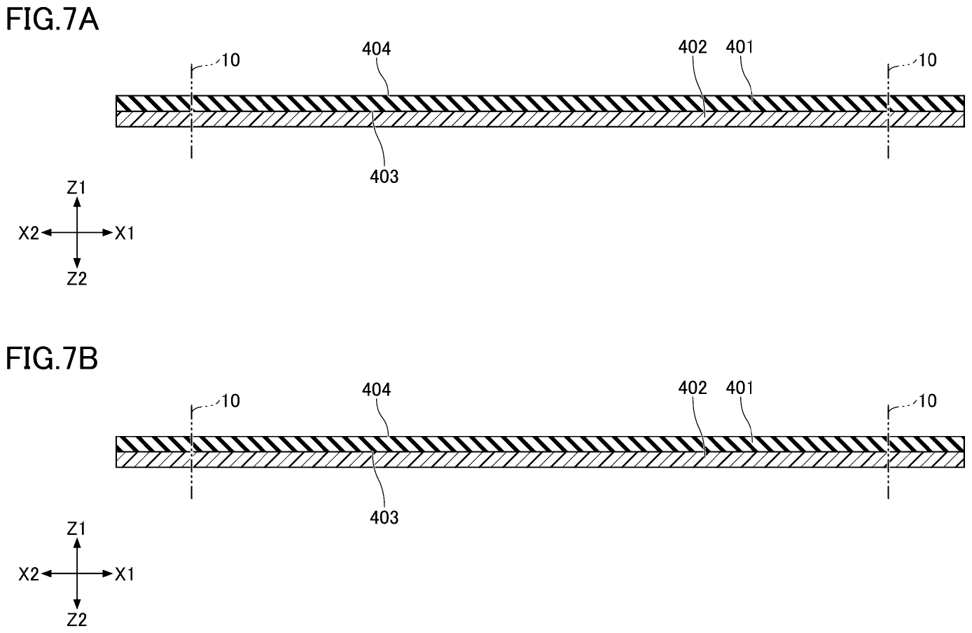

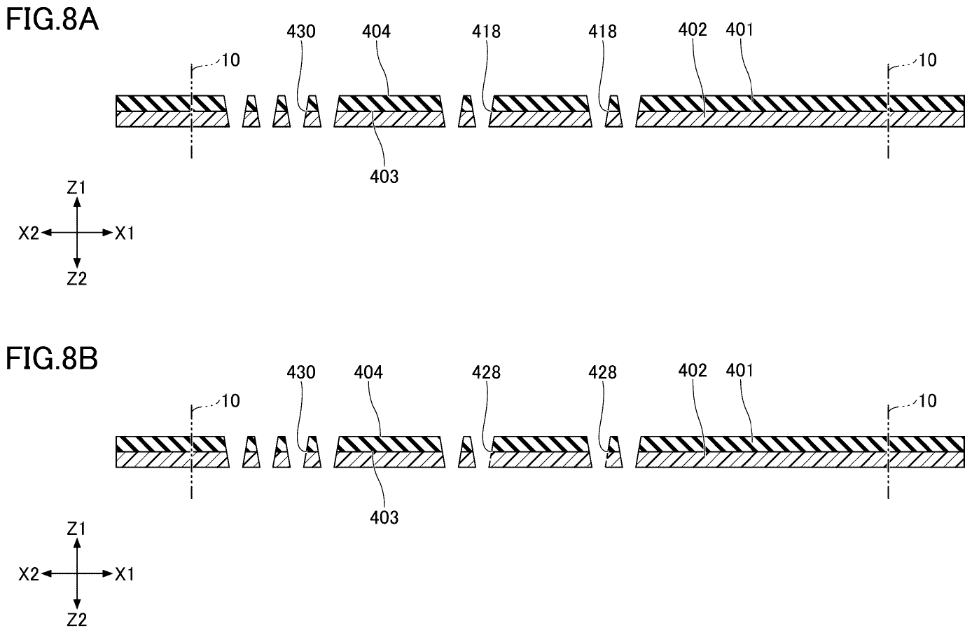

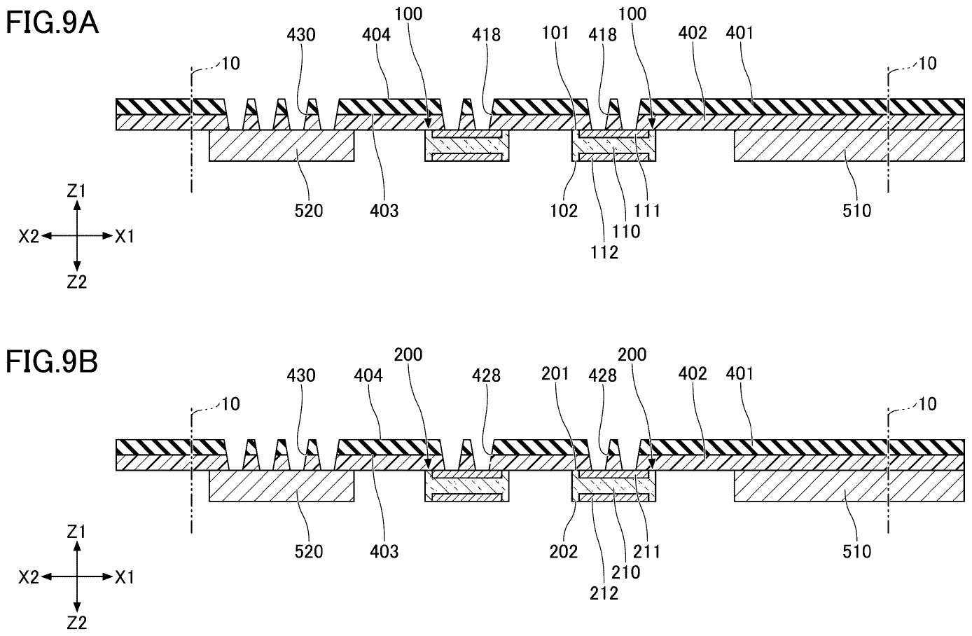

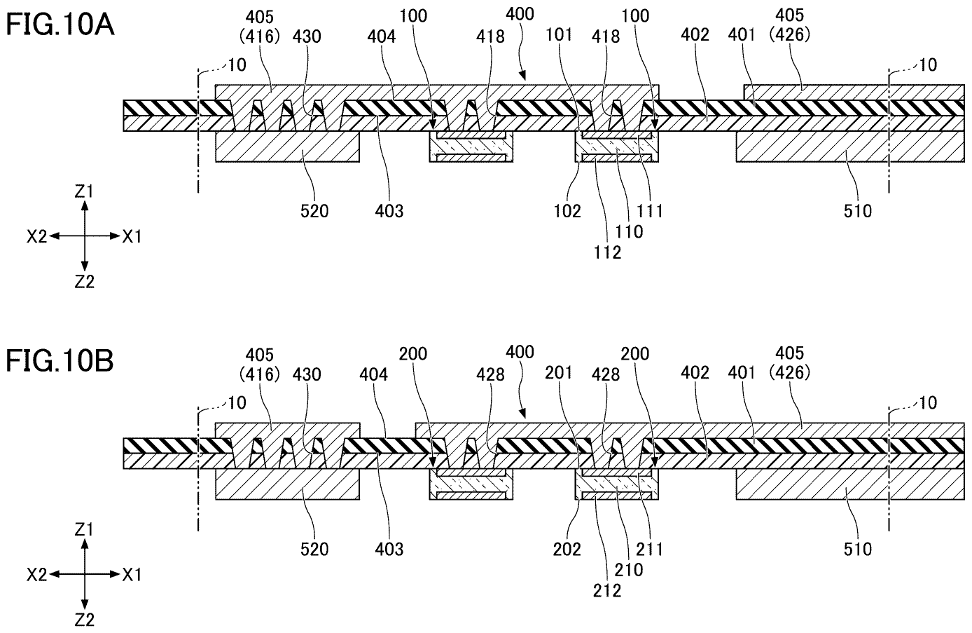

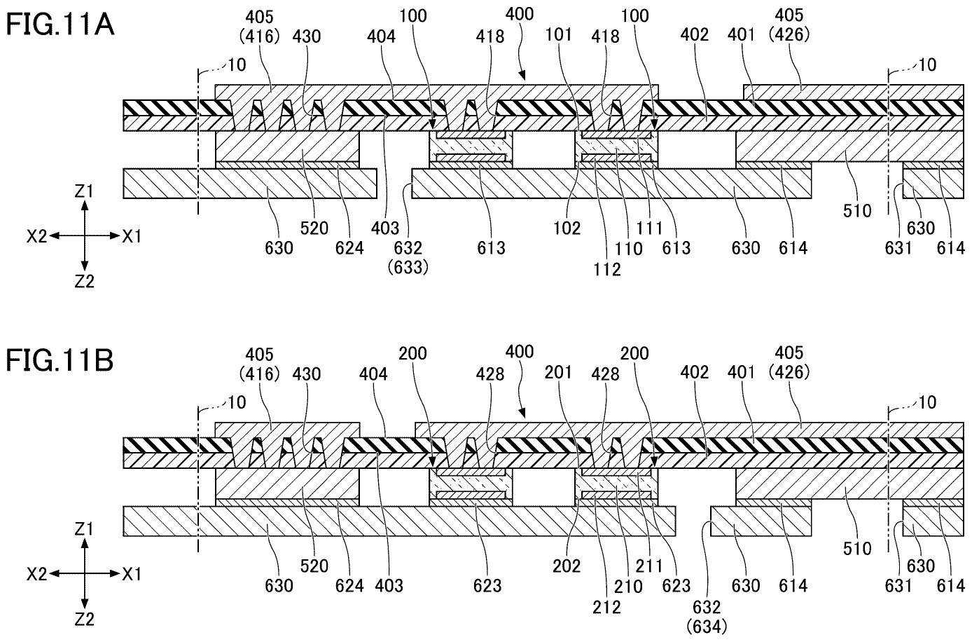

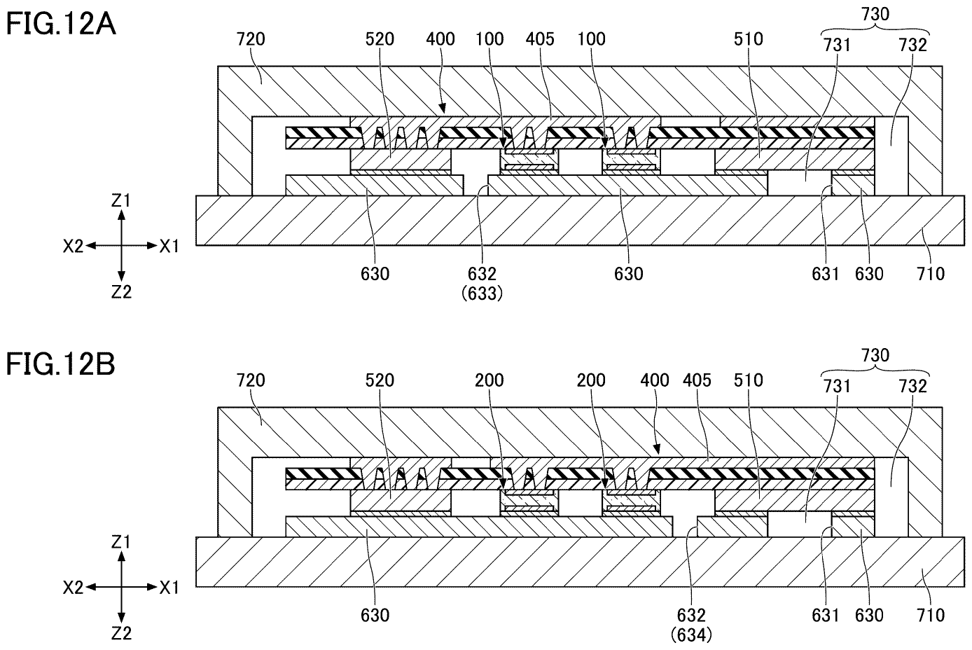

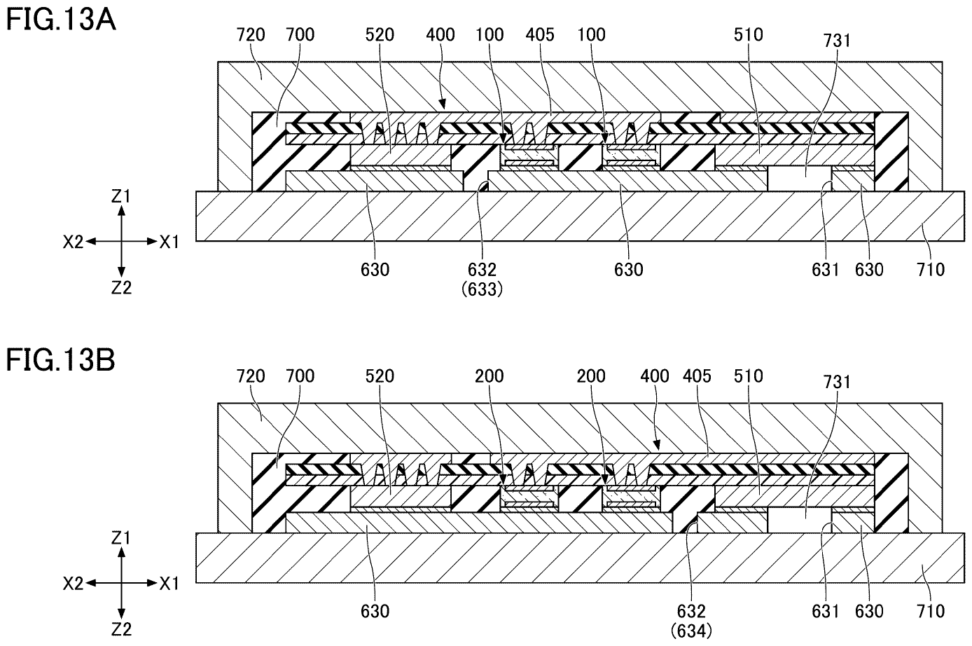

Next, a method for manufacturing the power module 1 will be described. FIG. 7A, FIG. 7B, FIG. 8A, FIG. 8B, FIG. 9A, FIG. 9B, FIG. 10A, FIG. 10B, FIG. 11A, FIG. 11B, FIG. 12A, FIG. 12B, FIG. 13A, and FIG. 13B are cross sectional views schematically illustrating the method for manufacturing the power module 1 according to the first embodiment.

First, as illustrated in FIG. 7A and FIG. 7B, a stack of the insulating base material 401 and the adhesive layer 402 is prepared. In the plan view, the insulating base material 401 and the adhesive layer 402 are larger than the final insulating base material 401 and the final adhesive layer 402 in the power module 1, respectively. The insulating base material 401 and the adhesive layer 402 are cut later along a cutting line 10, to obtain the final insulating base material 401 and the final adhesive layer 402.

Next, as illustrated in FIG. 8A and FIG. 8B, the through hole 418, the through hole 419 (refer to FIG. 3), the through hole 428, the through hole 429 (refer to FIG. 3), and the through hole 430 are formed in the insulating base material 401 and the adhesive layer 402. The through holes 418, 419, 428, 429, and 430 can be formed by a laser processing or machining using a CO₂ laser, a UV-YAG laser, or the like, or by a punching process, for example. The through hole 418 is an example of a first through hole, the through hole 428 is an example of a second through hole, and the through hole 430 is an example of a third through hole.

Next, as illustrated in FIG. 9A and FIG. 9B, the semiconductor devices 100, the semiconductor devices 200, the shim 510, and the shim 520 are adhered to the insulating base material 401 by the adhesive layer 402. In this state, the first surface 101 of the semiconductor device 100 is caused to face the first surface 403 of the insulating base material 401, and an alignment is performed so that the electrode 111 overlaps the through hole 418 and the electrode 113 overlaps the through hole 419 in the plan view. That is, the alignment is performed so that the electrode 111 is exposed from the through hole 418 and the electrode 113 is exposed from the through hole 419. Further, the first surface 201 of the semiconductor device 200 is caused to face the first surface 403 of the insulating base material 401, and an alignment is performed so that the electrode 211 overlaps the through hole 428 and the electrode 213 overlaps the through hole 429 in the plan view. That is, the alignment is performed so that the electrode 211 is exposed from the through hole 428 and the electrode 213 is exposed from the through hole 429. Further, the shim 520 is aligned so that a surface (a surface on the Z1-side) of the shim 520 overlaps the through hole 430 in the plan view. That is, the shim 520 is positioned so as to be exposed from the through hole 430.

Next, as illustrated in FIG. 10A and FIG. 10B, the interconnect layer 405 is formed on the second surface 404 of the insulating base material 401. The interconnect layer 405 may be formed by a semi-additive method, for example. The interconnect layer 405 includes the interconnect 416, the interconnect 416A (refer to FIG. 1), the interconnect 417 (refer to FIG. 1), the interconnect 426, the interconnect 426A (refer to FIG. 1), and the interconnect 427 (refer to FIG. 1). The insulating base material 401, the adhesive layer 402, and the interconnect layer 405 constitute the flexible wiring board 400.

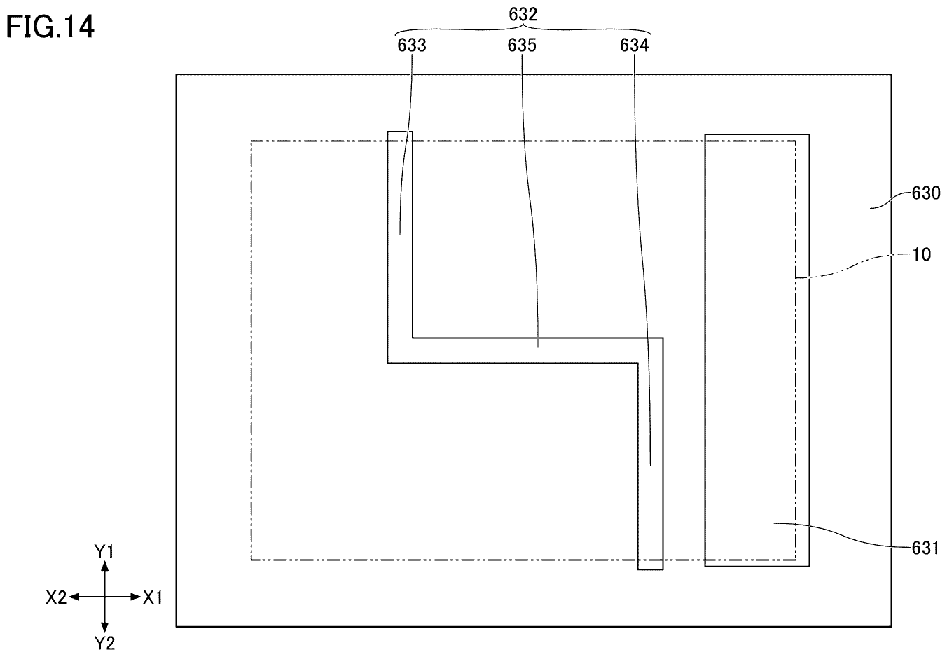

Next, as illustrated in FIG. 11A and FIG. 11B, the conductive bonding material 613 is provided on the second surface 102 of the semiconductor device 100, and the conductive bonding material 623 is provided on the second surface 202 of the semiconductor device 200. In addition, the conductive bonding material 614 is provided on the second surface (the surface on the Z2-side) of the shim 510, and the conductive bonding material 624 is provided on the second surface (the surface on the Z2-side) of the shim 520. For example, the conductive bonding material 614 is provided on a portion of the second surface of the shim 510 that does not overlap an opening 631 of a lead frame 630 (refer to FIG. 14) which will be described later.

Next, the lead frame 630 is bonded to the electrode 112 by the conductive bonding material 613, bonded to the electrode 212 by the conductive bonding material 623, bonded to the shim 510 by the conductive bonding material 614, and bonded to the shim 520 by the conductive bonding material 624. When performing the bonding of the lead frame 630, the conductive bonding materials 613, 614, 623, and 624 are cured. Next, the lead frame 630 will be described. FIG. 14 is a top view of the lead frame 630.

In the plan view, the lead frame 630 is larger than the lead terminals 610 and 620 in the power module 1. The lead terminals 610 and 620 are obtained by later cutting the lead frame 630 along the cutting line 10. The lead frame 630 has openings 631 and 632. The openings 631 and 632 penetrate the lead frame 630. The opening 631 is formed inside a contour of the shim 510 in the plan view. In addition, in the plan view, a portion of the cutting line 10 is located inside the opening 631, and a contour of the opening 631 and the cutting line 10 intersect each other. The opening 632 has a first portion 633, a second portion 634, and a third portion 635. The first portion 633 extends along the Y-axis between the shim 520 and the four semiconductor devices 100 in the plan view. The second portion 634 extends along the Y-axis between the shim 510 and the four semiconductor devices 200 in the plan view. The third portion 635 extends along the X-axis and connects an end portion of the first portion 633 on the Y2-side and a portion of the second portion 634 on the Y1-side. The opening 632 is formed between a portion where the lead terminal 610 is to be formed and a portion where the lead terminal 620 is to be formed. In the plan view, the end portion of the first portion 633 on the Y1-side is outside the cutting line 10, and the first portion 633 intersects the cutting line 10. In the plan view, the end portion of the second portion 634 on the Y2-side is located outside the cutting line 10, and the second portion 634 intersects the cutting line 10. The opening 631 is an example of a first opening, and the opening 632 is an example of a second opening.

Next, as illustrated in FIG. 12A and FIG. 12B, the structure illustrated in FIG. 11A and FIG. 11B is placed in a space 730 defined by a lower mold 710 and an upper mold 720 of a molding machine. In this state, a surface of the lead frame 630 on the Z2-side is brought into contact with a surface of the lower mold 710 on the Z1-side, and a surface of the interconnect layer 405 on the Z1-side is brought into contact with a surface of the upper mold 720 on the Z2-side. As a result, the space 730 includes a space 731 inside the opening 631 and a space 732 other than a space inside the opening 631, which are isolated from each other. The lower mold 710 and the upper mold 720 may include a cavity block and a liner.

Next, as illustrated in FIG. 13A and FIG. 13B, a resin is supplied into the space 732 in a state where the space 731 is closed by the lower mold 710, and the resin is cured to form the mold 700. Because the resin is not supplied into the space 731, the space 731 remains as it is. Accordingly, a portion of the surface of the shim 510 on the Z2-side is exposed from the mold 700. The surface of the interconnect layer 405 on the Z1-side, the surface of the lead terminal 610 on the Z2-side, and the surface of the lead terminal 620 on the Z2-side are also exposed from the mold 700.

Thereafter, the integrated structure illustrated in FIG. 11A and FIG. 11B and the mold 700 are taken out from the lower mold 710 and the upper mold 720, and cutting is performed along the cutting line 10. That is, the lead frame 630 is cut through the opening 631, the first portion 633, and the second portion 634. As a result, the lead terminal 610 and the lead terminal 620 are formed from the lead frame 630, and the power module 1 according to the first embodiment (refer to FIG. 1 through FIG. 4, FIG. 5A, and FIG. 5B) is obtained.

### Reference Example

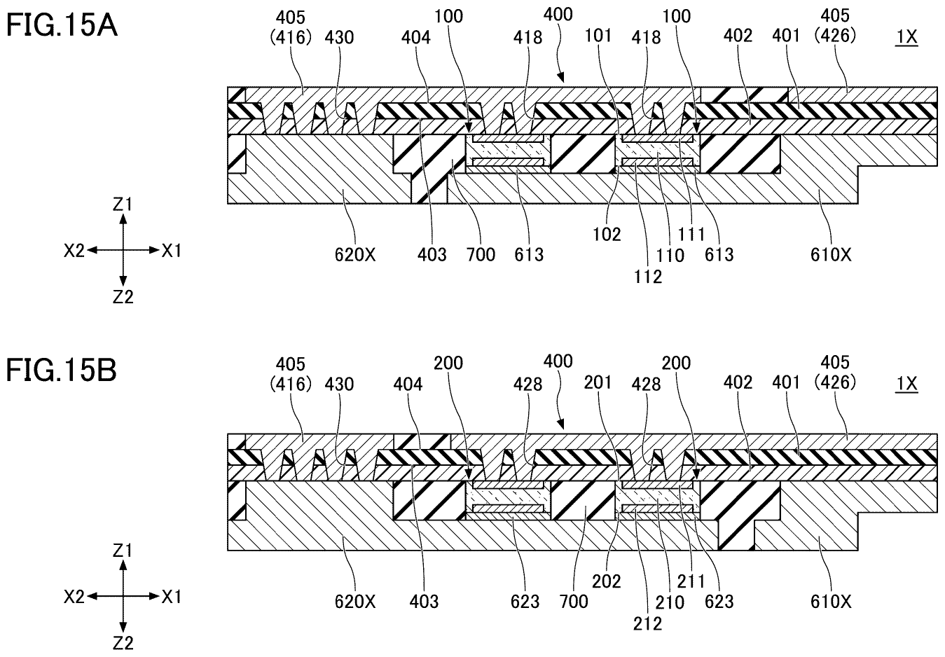

Next, a reference example for comparison with the first embodiment will be described. FIG. 15A and FIG. 15B are cross sectional views schematically illustrating a power module according to the reference example.

A power module 1X according to the reference example includes a lead terminal 610X in place of the lead terminal 610, the shim 510, and the conductive bonding material 614 of the power module 1, and includes a lead terminal 620X in place of the lead terminal 620, the shim 520, and the conductive bonding material 624 of the power module 1. The lead terminal 610X is bonded to the electrode 112 by the conductive bonding material 613, and is adhered to the insulating base material 401 by the adhesive layer 402. The lead terminal 620X is bonded to the electrode 212 by the conductive bonding material 623, and is adhered to the insulating base material 401 by the adhesive layer 402. Otherwise, the configuration of the power module 1X is the same as that of the power module 1.

In the case of the power module 1X, it is impossible to simultaneously adhere the lead terminal 610X to the insulating base material 401 by the adhesive layer 402 and bond the lead terminal 610X to the electrode 112 by the conductive bonding material 613. Similarly, it is impossible to simultaneously adhere the lead terminal 620X to the insulating base material 401 by the adhesive layer 402 and bond the lead terminal 620X to the electrode 212 by the conductive bonding material 623. In addition, it is not easy to perform the bonding after the adhesion or to perform the adhesion after the bonding.

Further, it is not easy to prevent the surface of the lead terminal 610X on the Z2-side corresponding to the shim 510 from being covered with the mold 700. Although it is conceivable to use a lead frame having a recess corresponding to the opening 631, the control associated with the forming of the recess is more complex compared to the control associated with the forming the opening 631 in the lead frame 630 having a flat plate shape.

Accordingly, it is very difficult to manufacture the power module 1X.

### Second Embodiment

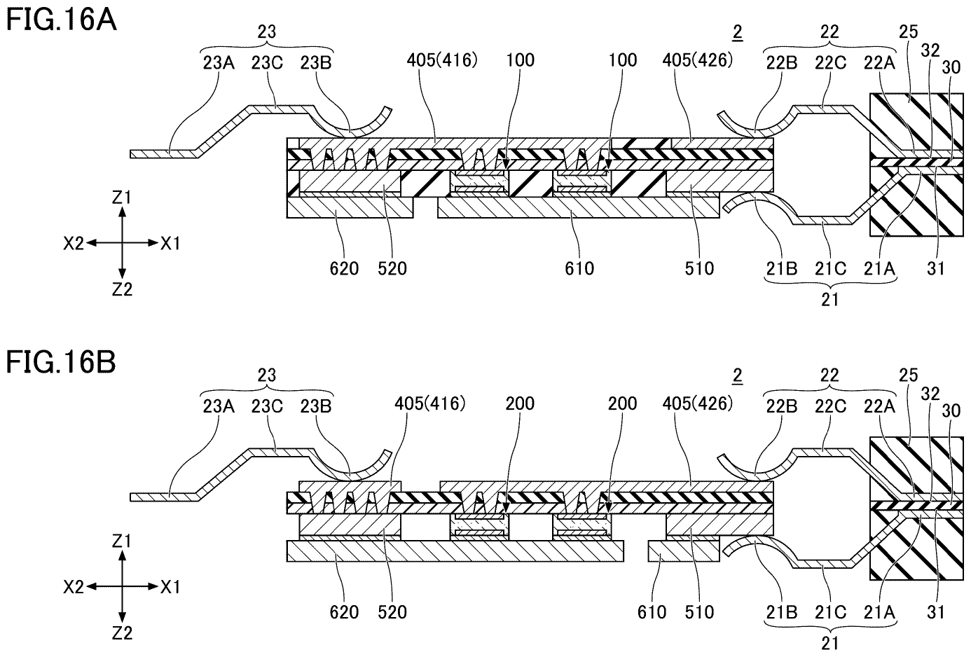

A second embodiment will be described. The second embodiment differs from the first embodiment in that an external terminal is provided. FIG. 16A and FIG. 16B are cross sectional views schematically illustrating the power module according to the second embodiment.

A power module 2 according to the second embodiment includes the power module 1, external terminals 21, 22, and 23, an insulating film 30, and a support member 25. The external terminals 21, 22, and 23 are formed of a metal plate, for example.

The insulating film 30 is provided between the external terminal 21 and the external terminal 22. The insulating film 30 has a first surface 31 facing the external terminal 21 and a second surface 32 opposite to the first surface 31 and facing the external terminal 22. For example, the external terminal 21 is in contact with the first surface 31 of the insulating film 30, and the external terminal 22 is in contact with the second surface 32 of the insulating film 30. A material used for the insulating film 30 is polyimide, for example.

The external terminal 21 includes a flat plate portion 21A, a curved portion 21B, and an intermediate portion 21C. In the flat plate portion 21A, the Z-axis direction is taken as a thickness direction, and the flat plate portion 21A extends along the X-axis. The intermediate portion 21C is continuous with an end portion of the flat plate portion 21A on the X2-side, and extends toward the X2-side and the Z2-side. The curved portion 21B is continuous with an end portion of the intermediate portion 21C on the X2-side, and protrudes toward the Z1-side. For example, the curved portion 21B has a substantially U-shape or a substantially J-shape in a cross sectional view perpendicular to the Y-axis. The external terminal 22 has a flat plate portion 22A, a curved portion 22B, and an intermediate portion 22C. In the flat plate portion 22A, the Z-axis direction is taken as a thickness direction, and the flat plate portion 22A extends along the X-axis. The intermediate portion 22C is continuous with an end portion of the flat plate portion 22A on the X2-side, and extends toward the X2-side and the Z1-side. The curved portion 22B is continuous with an end portion of the intermediate portion 22C on the X2-side, and protrudes toward the Z2-side. For example, the curved portion 22B has a substantially U-shape or a substantially J-shape in the cross sectional view perpendicular to the Y-axis.

The insulating film 30 is provided between the flat plate portion 21A and the flat plate portion 22A. The support member 25 supports the flat plate portion 21A, the flat plate portion 22A, and the insulating film 30. The support member 25 may support a portion of the intermediate portion 21C and a portion of the intermediate portion 22C. The curved portion 21B is in contact with the shim 510, and the curved portion 22B is in contact with the interconnect 426. For example, the intermediate portion 21C and the intermediate portion 22C are elastically deformed, the curved portion 21B is pressed against the shim 510, and the curved portion 22B is pressed against the interconnect 426, as in press-fit terminals. The external terminal 21 is an example of a first terminal, and the external terminal 22 is an example of a second terminal.

The external terminal 23 has a flat plate portion 23A, a curved portion 23B, and an intermediate portion 23C. The flat plate portion 23A has the Z-axis direction taken as a thickness direction, and the flat plate portion 23A extends along the X-axis. The intermediate portion 23C is continuous with an end portion of the flat plate portion 23A on the X1-side, and extends toward the X1-side and the Z1-side. The curved portion 23B is continuous with an end portion of the intermediate portion 23C on the X1-side and protrudes toward the Z2-side. For example, the curved portion 23B has a substantially U-shape or a substantially J-shape in the cross sectional view perpendicular to the Y-axis.

The curved portion 23B is in contact with the interconnect 416. For example, the intermediate portion 23C is elastically deformed, and the curved portion 23B is pressed against the interconnect 416, as in press-fit terminals. The external terminal 23 is an example of a third terminal.

In the power module 2, the external terminal 21 can be used as an external input terminal on the positive electrode side, the external terminal 22 can be used as an external input terminal on the negative electrode side, and the external terminal 23 can be used as an external output terminal.

According to the disclosed technique, it is possible to reduce the inductance of the power module.

Various aspects of the subject-matter described herein may be set out non-exhaustively in the following numbered clauses:

Clause 1. A method for manufacturing a power module, comprising:
forming a first through hole, a second through hole, and a third through hole in an insulating base material having a fifth surface and a sixth surface opposite to the fifth surface;
adhering a first semiconductor device having a first surface and a second surface opposite to the first surface, a first electrode provided at the first surface, and a second electrode provided at the second surface to the fifth surface so that the first electrode is exposed from the first through hole;
adhering a second semiconductor device having a third surface and a fourth surface opposite to the third surface, a third electrode provided at the third surface, and a fourth electrode provided at the fourth surface to the fifth surface so that the third electrode is exposed from the second through hole;
adhering a third conductive member to the fifth surface at a position separated from the first through hole, the second through hole, and the third through hole;
adhering a sixth conductive member to the fifth surface so as to be exposed from the third through hole;
forming a first conductive member electrically connected to the first electrode through the first through hole and electrically connected to the sixth conductive member through the third through hole, and a fourth conductive member electrically connected to the third electrode through the second through hole, on the sixth surface;
bonding a lead frame to the second electrode, the fourth electrode, the third conductive member, and the sixth conductive member after forming the first conductive member and the fourth conductive member;
forming an encapsulation member configured to encapsulate the first semiconductor device and the second semiconductor device after the bonding the lead frame; and
cutting the lead frame after the forming the encapsulation member to form a second conductive member electrically connected to the second electrode and the third conductive member, and a fifth conductive member electrically connected to the fourth electrode and the sixth conductive member, from the lead frame, wherein:
the lead frame has a first opening located inside a contour of the third conductive member in a plan view and a second opening located between a portion where the second conductive member is to be formed and a portion where the fifth conductive member is to be formed,
the encapsulation member is formed in a state where the first opening is closed by a mold, and
the lead frame is cut through the first opening.

Clause 2. The method for manufacturing the power module according to clause 1, wherein the first conductive member penetrates the insulating base material and is in contact with the sixth conductive member.

Clause 3. The method for manufacturing the power module according to clause 1, wherein the first conductive member is exposed from the encapsulation member.

Clause 4. The method for manufacturing the power module according to clause 1, wherein a thickness of the insulating base material is 50 μm or greater and 100 μm or less.

Although the embodiments are numbered with, for example, “first,” or “second,” the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A power module comprising:
a first semiconductor device having a first surface and a second surface opposite to the first surface, a first electrode provided at the first surface, and a second electrode provided at the second surface;
a second semiconductor device having a third surface and a fourth surface opposite to the third surface, a third electrode provided at the third surface, and a fourth electrode provided at the fourth surface;
an insulating base material having a fifth surface to which the first semiconductor device and the second semiconductor device are adhered and a sixth surface opposite to the fifth surface;
a first conductive member penetrating the insulating base material, electrically connected to the first electrode, and formed on the sixth surface;
a second conductive member electrically connected to the second electrode;
a third conductive member adhered to the fifth surface and electrically connected to the second conductive member;
a fourth conductive member penetrating the insulating base material, electrically connected to the third electrode, and formed on the sixth surface;
a fifth conductive member electrically connected to the fourth electrode;
a sixth conductive member adhered to the fifth surface and electrically connected to the fifth conductive member; and
an encapsulation member configured to encapsulate the first semiconductor device and the second semiconductor device, wherein:
the first conductive member and the sixth conductive member are electrically connected,
the third conductive member and the fourth conductive member overlap each other in a plan view, and
the third conductive member and the fourth conductive member extend to an outside of the encapsulation member.

2. The power module as claimed in claim 1, further comprising:
a first conductive bonding material configured to bond the second electrode and the second conductive member;
a second conductive bonding material configured to bond the third conductive member and the second conductive member;
a third conductive bonding material configured to bond the fourth electrode and the fifth conductive member; and
a fourth conductive bonding material configured to bond the sixth conductive member and the fifth conductive member.

3. The power module as claimed in claim 1, wherein:
the third conductive member includes a first conductive shim, and
the sixth conductive member includes a second conductive shim.

4. The power module as claimed in claim 3, wherein a thickness of the first conductive shim and a thickness of the second conductive shim are 50 μm or greater and 500 μm or less.

5. The power module as claimed in claim 1, wherein the first conductive member penetrates the insulating base material and is in contact with the sixth conductive member.

6. The power module as claimed in claim 1, wherein the first conductive member is exposed from the encapsulation member.

7. The power module as claimed in claim 1, wherein a thickness of the insulating base material is 50 μm or greater and 100 μm or less.

8. The power module as claimed in claim 1, further comprising:
a first terminal in contact with the third conductive member outside the encapsulation member; and
a second terminal in contact with the fourth conductive member outside the encapsulation member.

9. The power module as claimed in claim 8, further comprising:
a third terminal in contact with the first conductive member outside the encapsulation member.
